(19) United States
(12) Patent Application Publication
(10) Pub. No.: US 2025/0226824 A1
(43) Pub. Date: Jul. 10, 2025

(54) LOAD SWITCH CIRCUIT AND CONTROLLING CIRCUIT OF THE SAME

(71) Applicant: Chengdu Monolithic Power Systems Co., Ltd., Chengdu (CN)

(72) Inventors: Xiangyi Yang, Chengdu (CN); Wei Mao, Chengdu (CN)

(21) Appl. No.: 19/009,184

(22) Filed: Jan. 3, 2025

(30) Foreign Application Priority Data
Jan. 5, 2024 (CN) 202410019047.6

(51) Int. Cl. H03K 17/687

(52) U.S. Cl. CPC H03K 17/6874

(57) ABSTRACT

The present invention discloses a load switch circuit including a switching element and a controlling circuit. The switching element is coupled between an input terminal and an output terminal of the load switch circuit. The controlling circuit coupled to the switching element, and is configured to regulate a set current limit of a load current flowing through the switching element. The controlling circuit is configured to control a loop formed by the controlling circuit and the switching element based on a sensed signal indicative of the current flowing through the switching element, so that the loop remains stable when the set current limit is changed from a first set current limit to a second set current limit. The load switch circuit provided by the present invention can stabilize the current regulation loop even when the set current limit changes in a larger dynamic range.

### CROSS-REFERENCE TO RELATED APPLICATIONS

This application claims priority to, and the benefit of, Chinese application No. 202410019047.6 filed on Jan. 5, 2024, which is incorporated herein by reference in its entirety.

### TECHNICAL FIELD

The present invention relates to electronic circuits, and in particular, but not exclusively, it relates to a load switch circuit used in electronic devices and a controlling circuit of the load switch circuit.

### BACKGROUND

A load switch circuit is widely used in electronic devices to connect or disconnect a power supply with its load. FIG. 1 shows a typical application 100 of a conventional load switch circuit 101. A critical device of the load switch circuit 101 is a switching device 102. As shown in FIG. 1, the load switch circuit 101 includes an input terminal VIN, an output terminal VOUT, an enable terminal EN and a ground terminal GND. The input terminal VIN is connected to a power supply, and the output terminal VOUT is connected to a load. The enable terminal EN is configured to receive an enable signal, and the switching device 102 is controlled to be turned on and off by the enable signal EN, so that the power supply is connected or disconnected with the load. Typical applications of the load switch circuit include removable circuit boards (for example, an extended circuit board), hot-swappable storage devices, and other applications involving connecting or disconnecting the power supply with the load (for example, charging applications supporting charging protocols such as USB PD3.0 and Type-C).

The above-mentioned traditional load switch circuit cannot respond quickly and regulate a load current to a desired current limit when the load changes.

### SUMMARY

The present invention provides an improved load switch circuit and a controlling circuit of the load switch circuit to solve the above problems.

An embodiment of the present invention provides a load switch circuit. The load switch circuit includes a switching element and a controlling circuit. The switching element is coupled between an input terminal and an output terminal of the load switch circuit. The controlling circuit is coupled to the switching element and is configured to regulate a load current flowing through the switching element to a set current limit. The controlling circuit is configured to control a loop formed by the controlling circuit and the switching element based on a sensed signal indicative of the current flowing through the switching element, so that the loop remains stable when the set current limit is changed from a first set current limit to a second set current limit.

The present invention also provides a load switch circuit. The load switch circuit includes a switching element and a controlling circuit. The switching element is coupled between an input terminal and an output terminal of the load switch circuit. The controlling circuit is coupled to the switching element and forms a loop with the switching element and is configured to regulate a current flowing through the switching element to a set current limit. The controlling circuit is configured to control a gain of the controlling circuit to be linearly proportional to the current flowing through the switching element, so that the loop remains stable when the set current limit changes from a first set current limit to a second set current limit.

The present invention further provides a controlling circuit of a load switch circuit. The load switch circuit includes a switching element coupled between an input terminal and an output terminal of the load switch circuit. The controlling circuit is coupled to the switching element and is configured to regulate a current flowing through the switching element a set current limit. The controlling circuit is further configured to control a loop formed by the controlling circuit and the switching element based on a sensed signal indicative of the current flowing through the switching element, so that the loop remains stable when the set current limit is changed from a first set current limit to a second set current limit.

The present invention further provides a controlling circuit of a load switch circuit. The load switch circuit includes a switching element coupled between an input terminal and an output terminal of the load switch circuit. The controlling circuit is coupled to the switching element and forms a loop with the switching element, and is configured to regulate a current flowing through the switching element to a set current limit. The controlling circuit is further configured to control a gain of the controlling circuit to be linearly proportional to the current flowing through the switching element, so that the loop remains stable when the set current limit is changed from a first set current limit to a second set current limit.

Compared with the prior art, the load switch circuit and the controlling circuit of the load switch circuit according to an embodiment of the present invention can stabilize the current regulation loop even the set current limit of the loop changes in a larger dynamic range.

### BRIEF DESCRIPTION OF DRAWINGS

The purpose, specific structural features and advantages of the present invention can be further understood by describing some embodiments of the present invention and the attached drawings.

FIG. 1 shows a typical application of a traditional load switch circuit.

FIG. 2 shows an exemplary structural block diagram of a load switch circuit, according to an embodiment of the present invention.

FIG. 3 shows an exemplary circuit diagram of a load switch circuit, according to an embodiment of the present invention.

FIG. 4 shows an exemplary circuit diagram of a load switch circuit, according to another embodiment of the present invention.

FIG. 5 shows an exemplary circuit diagram of a differential amplifier circuit, according to an embodiment of the present invention.

### DETAILED DESCRIPTION

Hereinafter, specific embodiments of the present invention will be described in detail, and it should be noted that the embodiments described here are only for illustration and are not used to limit the present invention. In the following detailed description of the present invention, numerous details are set forth in order to better understand the present invention. However, it will be understood by those skilled in the art that the invention may be practiced without these specific details. In order to explain the invention clearly, the detailed description of some specific structures and functions is simplified in herein. In addition, similar structures and functions that have been described in detail in some embodiments are not repeated in other embodiments. Although various terms of the present invention are described in connection with specific exemplary embodiments, these terms should not be construed as limited to the exemplary embodiments set forth herein.

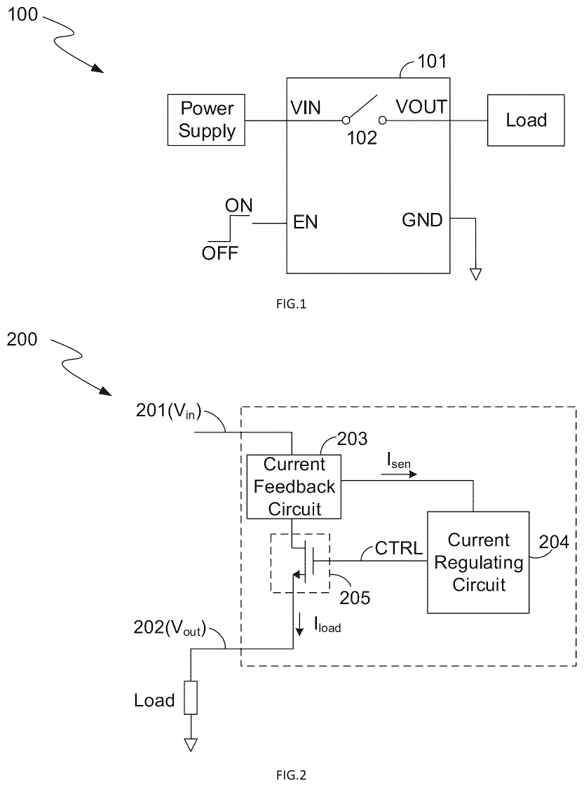

FIG. 2 shows an exemplary block diagram of a load switch circuit 200, according to an embodiment of the present invention. According to an embodiment of the present invention, the load switch circuit 200 is configured to receive an input voltage Vᵢₙ from a power supply (not shown) and provide an output voltage Vₒᵤₜ to a load. Referring to FIG. 2, the load switch circuit 200 may include an input terminal 201, an output terminal 202, a current feedback circuit 203, a current regulating circuit 204 and a switching element 205. The connection relationship of these components is as shown in FIG. 2. Although typical components of the load switch circuit 200 are provided in FIG. 2, there may be more or fewer components within the load switch circuit 200.

In an embodiment, the input terminal 201 is coupled to the power supply and receive the input voltage Vᵢₙ from the power supply. The output terminal 202 is coupled to the load for providing the output voltage Vₒᵤₜ to the load.

In an embodiment, the switching element 205 is coupled between the input terminal 201 and the output terminal 202 for converting the input voltage Vᵢₙ to the output voltage Vₒᵤₜ. In an embodiment, the switching element 205 is a FET (Field Effect Transistor, e.g., shown as an N-type field effect transistor in FIG. 2). For example, the switching element 205 may be a MOSFET (Metal Oxide Semiconductor FET), a Junction Field-Effect Transistor (JFET) or the like. In a specific embodiment, the switching element 205 is a power MOSFET. As shown in FIG. 2, a first terminal (e.g., a drain terminal) of the switching element 205 is coupled to the input terminal 201, a second terminal (e.g., a source terminal) is coupled to the output terminal 202, and a control terminal (e.g., a gate terminal) is coupled to the current regulating circuit 204 to receive a controlling signal CTRL. By controlling the turn-on and turn-off of the switching element 205 with the controlling signal CTRL, a path between the power supply and the load can be connected or disconnected.

In an embodiment, the current feedback circuit 203 is configured to sense a load current I_{load} flowing from the input terminal 201 to the load via the switching element 205, and then feedback/transmit the sensed current Iₛₑₙ (or, also referred to as a feedback current) indicative of the load current I_{load} to the current regulating circuit 204. In an embodiment, a value of the feedback current is proportional to a value of the load current I_{load}. In an embodiment, the current regulating circuit 204 may generate the controlling signal CTRL based on the feedback current. The controlling signal CTRL controls the gate terminal of the switching element 205 (for example, by controlling a voltage drop of the switching element 205), so as to regulate the load current l_{load} flowing from the input terminal 201 to the output terminal 202 via the switching element 205. Thus, the load current l_{load} can be kept at a desired current value (hereinafter referred to as a set current limit). The details about how to regulate the load current l_{load} by the current regulating circuit 204 will be described below.

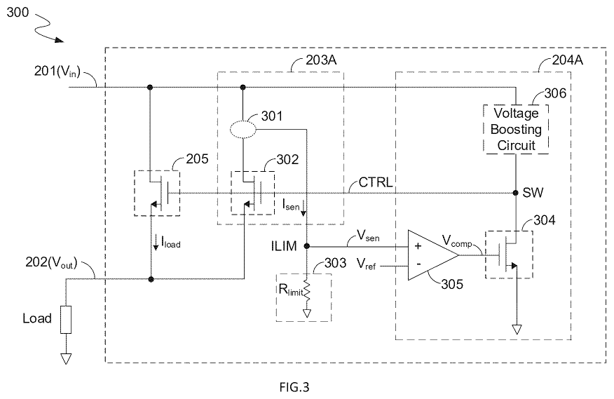

FIG. 3 shows an exemplary circuit diagram of a load switch circuit 300, according to an embodiment of the present invention. The load switch circuit 300 is a specific embodiment of the load switch circuit 200 in FIG. 2. As shown in FIG. 3, the load switch circuit 300 includes an input terminal 201, an output terminal 202, a switching element 205, a current feedback circuit 203A, a current limit adjustment element 303 and a current regulating circuit 204A. FIG. 3 will be described in conjunction with FIG. 2. For the sake of conciseness, the parts in FIG. 3 similar to those in FIG. 2 will not be described again.

The current feedback circuit 203A is a specific embodiment of the current feedback circuit 203. As shown in FIG. 3, the current feedback circuit 203A includes a current sensing circuit 301 and a transistor 302. The connection relationship of these components is as shown in FIG. 3.

In an embodiment, the transistor 302 is connected in parallel with the switching element 205 and forms a current mirror structure with the switching element 205, so that a current flowing through the transistor 302 is proportional to the load current I_{load} flowing through the switching element 205. Hereinafter, a ratio of the current flowing through the transistor 302 to the load current I_{load} can be expressed as K₁. A value of K₁ is related to sizes of the transistor 302 and the switching element 205. For example, in an example where the size of the transistor 302 is 1/10000 of the size of the switching element 205, the current flowing through the transistor 302 equals to I_{load}/10000.

In an embodiment, the current sensing circuit 301 is configured to sense a current flowing from the input terminal 201 through the transistor 302. Hereinafter, the sensed current will be referred to as a sensed current Iₛₑₙ. As mentioned above, the sensed current Iₛₑₙ is proportional to the load current I_{load} (for example, 1/10000). For example, the current sensing circuit 301 may include a current sensing resistor connected in series with the transistor 302, and a current flowing through the current sensing resistor may be measured by measuring a voltage across the current sensing resistor. The circuit structure of the current sensing circuit 301 is not specifically described here, but a person skilled in the art can design any suitable current sensing circuit 301 to sense the current flowing from the input terminal 201 (for example, to the load) through the transistor 302.

In an embodiment, as shown in FIG. 3, the sensed current Iₛₑₙ sensed by the current sensing circuit 301 further flows to a resistor Rlimit, and the sensed current Iₛₑₙ is indicated by a voltage Vₛₑₙ (i.e., a voltage on a current limit adjusting terminal ILIM) across the resistor Rlimit. The sensed voltage Vₛₑₙ may follow the following relationship: Vₛₑₙ−Rₗᵢₘᵢₜ×Iₛₑₙ=Rₗᵢₘᵢₜ×K₁×I_{load} (1), where Rₗᵢₘᵢₜ represents a resistance value of the resistor Rlimit and K₁ represents a ratio of the sensed current Iₛₑₙ to the load current I_{load}. It can be seen from the relationship (1) that the value of the sensed voltage Vₛₑₙ is proportional to the value of the load current l_{load}. In an embodiment, the resistor Rlimit may be configured to adjust the current limit of the load current to a desired set current limit. In an embodiment, the resistor Rlimit may be a variable resistor. The user can adjust the set current limit of the load current for example from a first set current limit (e.g., 20 A) to a second set current limit (e.g., 50 mA) by adjusting the resistance value of the resistor Rlimit.

The current regulating circuit 204A is an embodiment of the abovementioned current regulating circuit 204 shown in FIG. 2. As shown in FIG. 3, the current regulating circuit 204A includes a transistor 304, an error amplifier circuit 305 and a voltage boosting circuit 306. The connection relationship of these components is as shown in FIG. 3.

In an embodiment, the error amplifier circuit 305 has a first input terminal (e.g., a noninverting input terminal), a second input terminal (e.g., an inverting input terminal), and an output terminal. The first input terminal of the error amplifier circuit 305 receives the sensed voltage Vₛₑₙ indicative of the load current h, and the second input terminal receives a reference voltage V_{ref}, and the error amplifier circuit 305 generates an error amplification signal V_{comp} on the output terminal based on a difference between the sensed voltage Vₛₑₙ and the reference voltage V_{ref}.

In an embodiment, in order to maintain the load current I_{load} at the desired set current limit, it is generally necessary to regulate the sensed voltage Vₛₑₙ to be equal to (or substantially equal to) the reference voltage V_{ref}, that is, Vₛₑₙ=Rₗᵢₘᵢₜ×K₁×I_{load}=V_{ref} (2). Since the reference voltage V_{ref} is a fixed value, it can be known that the resistance value of the resistor Rlimit is inversely proportional to the value of the load current I_{load} in a steady state. For example, assuming that the desired value of the load current I_{load} (or the desired set current limit) is 50 mA, it is needed that the sensed voltage Vₛₑₙ to be equal to the reference voltage V_{ref}, that is, Vₛₑₙ=V_{ref}. In this example, assuming that the reference voltage V_{ref} has a fixed value of 0.4V, then according to the relation (2), we can know that: 0.4=Rₗᵢₘᵢₜ× 1/10000×0.05. That is, the resistance value of the resistor Rlimit needs to be adjusted to 80 KΩ. In another example, assuming that the desired value of the load current I_{load} (or the set current limit) is 2 A, then the resistance value of the resistor Rlimit needs to be adjusted to 2 kΩ. In an embodiment, the desired value of the load current I_{load} (or the set current limit) may be determined according to the input voltage Vᵢₙ and the output voltage Vₒᵤₜ and/or the system load.

In an embodiment, the transistor 304 includes a first terminal (e.g., a drain terminal), a second terminal (e.g., a source terminal) and a control terminal (e.g., a gate terminal). As shown in FIG. 3, the first terminal of the transistor 304 is coupled to a switching node SW, the second terminal is coupled to a reference ground, and the control terminal is coupled to the output terminal of the error amplifier circuit 305 to receive the error amplification signal V_{comp}. In an embodiment, the error amplification signal V_{comp} may be configured to adjust a voltage on the switching node SW by controlling the control terminal of the transistor 304 (for example, by adjusting the voltage drop between the first terminal and the second terminal of the transistor 304). As mentioned above, the voltage on the switching node SW can be used as the controlling signal CTRL for controlling the switching element 205 and the transistor 302. For example, when the load current I_{load} of the load switch circuit 300 suddenly changes, for example, becomes larger, the sensed voltage Vₛₑₙ on the first input terminal of the error amplifier circuit 305 will become larger than the reference voltage V_{ref}, and the error amplification voltage V_{comp} on the output terminal of the error amplifier circuit 305 will become larger. As the error amplification voltage V_{comp} becomes larger, the voltage drop of the transistor 304 will become smaller, so that the voltage on the switching node SW will decrease. The decreased voltage on the switching node SW will control the gate terminals of the switching element 205 and the transistor 302, so as to regulate the load current I_{load} back to the set current limit.

In an embodiment, an output termina of the voltage boosting circuit 306 is connected to the switching node SW for boosting the voltage on the switching node SW, thereby ensuring that the switching element 205 and the transistor 302 can be properly turned on. In an embodiment, the voltage boosting circuit 306 includes a charge pump. It should be understood that the voltage boosting circuit 306 is usually used when the switching element 205 and the transistor 302 are N-type FET. In an example where the switching element 205 and the transistor 302 are P-type FET, the current regulating circuit 204A may not include the voltage boosting circuit 306.

The circuit structure shown in FIG. 3 forms a current regulation loop for regulating the load current. At the steady state, a gain of this loop Loop Gain₁ can be expressed as the following relationship:

$$Loop {Gain}_{1} = {A}_{305} \times {A}_{304} \times {gm}_{205} \times {R}_{limit} \times {K}_{1} , \qquad ( 3 )$$

where A₃₀₅ represents a gain of the error amplifier circuit 305, A₃₀₄ represents a gain of the transistor 304, gm₂₀₅ represents a transconductance of the switching element 205, Rₗᵢₘᵢₜ represents the resistance value of the resistor Rlimit, and K₁ represents the ratio of the sensed current Iₛₑₙ to the load current I_{load}.

Assuming each of the switching element 205 and the transistor 304 is a MOSFET, the transconductance gm of the MOSFET can generally be expressed as:

$$gm = \sqrt{2 {μ}_{n} {C}_{ox} \frac{W}{L} {I}_{d}} , \qquad ( 4 )$$

where μₙ represents an electron mobility of the MOSFET, Cₒₓ represents a gate oxide capacitance per unit area of the MOSFET,

$$\frac{W}{L}$$

represents a width-length ratio of the MOSFET, and I_{d} represents a drain current of the MOSFET.

For the switching element 205, since its drain current is the load current I_{load}, its transconductance can be expressed as

$${gm}_{205} = \sqrt{2 {μ}_{n} {C}_{ox} \frac{W}{L} {I}_{load}} , \qquad ( 5 )$$

and then it can be known that gm₂₀₅∝\sqrt{I_{load}} (6).

At the steady state, Vₛₑₙ=V_{ref}, that is, Rₗᵢₘᵢₜ×K₁×I_{load}=V_{ref} (7), and also K₁ and V_{ref} are usually constant. Therefore, it can be concluded that

$${R}_{limit} ∝ \frac{1}{{I}_{load}} . \qquad ( 8 )$$

Substituting relations (6) and (8) into relation (3), we can know that

$$Loop {Gain}_{1} ∝ \frac{1}{\sqrt{{I}_{load}}} . \qquad ( 9 )$$

According to the above relationship (9), the loop gain Loop Gain₁ of the circuit shown in FIG. 3 is inversely proportional to \sqrt{I_{load}}. That is, when the value of the load current I_{load} is regulated to the desired value (set current limit), although gm₂₀₅ varies with the load current I_{load} and the resistor Rlimit also varies with the load current I_{load}, the change of gm₂₀₅ cannot compensate the change of the resistor Rlimit, so that the loop gain Loop Gain₁ cannot maintain stable when the set current limit of the load current I_{load} changes. This situation is especially obvious when the range of the set current limit of the load current I_{load} is relatively wide. For example, when the current limit of the load current I_{load} is adjusted from 50 mA to 2 A or more, the loop gain Loop Gain₁ will greatly increase, thus making the loop unstable. For example, the loop being stable mentioned here can mean that the gain of the loop is basically unchanged within the error margin allowed in the engineering practice.

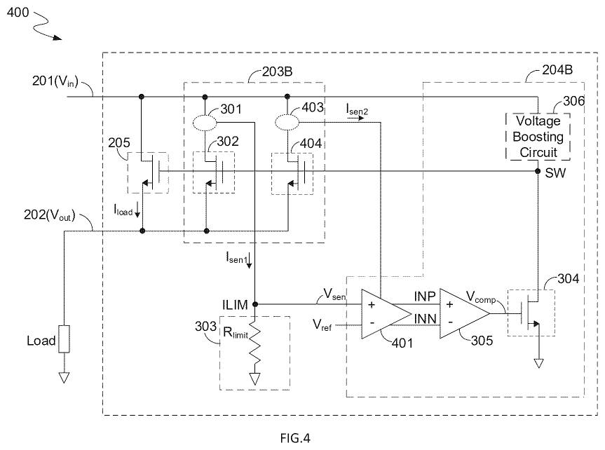

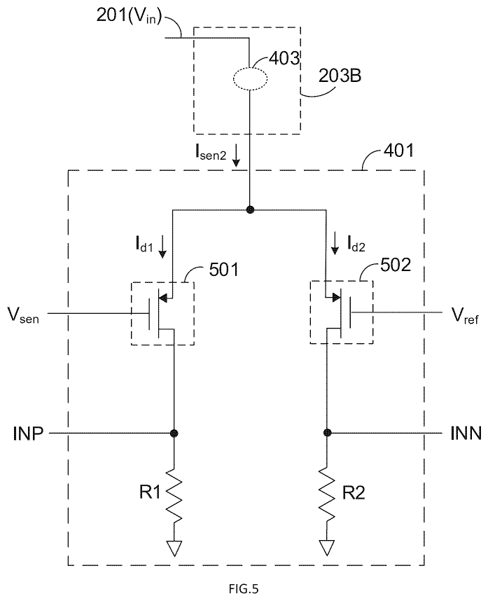

Based on this, another embodiment of the present invention further proposes an improved load switch circuit as shown in FIG. 4.

FIG. 4 shows an exemplary circuit diagram of a load switch circuit 400, according to another embodiment of the present invention. The load switch circuit 400 is another specific embodiment of the load switch circuit 200. FIG. 4 will be described in conjunction with FIGS. 2 and 3. For the sake of conciseness, the parts in FIG. 4 that are similar to those in FIGS. 2 and 3 will not be described again.

A current regulating circuit 204B in FIG. 4 may be another embodiment of the current regulating circuit 204 in FIG. 2. Referring to FIG. 4, the current regulating circuit 204B includes a transistor 304, an error amplifier circuit 305, a voltage boosting circuit 306 and a differential amplifier circuit 401. The connection relationship of these components is as shown in FIG. 4. The current regulating circuit 204B in FIG. 4 has a similar structure to the current regulating circuit 204A in FIG. 3, except that the current regulating circuit 204B further includes the differential amplifier circuit 401. For the sake of brevity, descriptions of the similar parts will not be repeated.

As shown in FIG. 4, in an embodiment, the differential amplifier circuit 401 includes a differential amplifier circuit with two input terminals and two output terminals. The differential amplifier circuit 401 includes a first input terminal (for example, a noninverting input terminal), a second input terminal (for example, an inverting input terminal), a first output terminal and a second output terminal. For example, the first input terminal of the differential amplifier circuit 401 receives the sensed voltage Vₛₑₙ indicative of the load current I_{load}, and the second input terminal receives the reference voltage V_{ref}, and then the differential amplifier circuit 401 amplifies a difference between the sensed voltage Vₛₑₙ and the reference voltage V_{ref} to generate/output a first amplified signal INP on the first output terminal and a second amplified signal INN on the second output terminal, respectively. A difference between the first amplified signal INP and the second amplified signal INN is A₄₀₁ times of the difference between the sensed voltage Vₛₑₙ and the reference voltage V_{ref}, where A₄₀₁ is a gain of the differential amplifying circuit 401.

In addition, the differential amplifier circuit 401 also includes a bias terminal for receiving a bias current and providing the bias current for the differential amplifier circuit 401, so that the differential amplifier circuit 401 can work in a linear amplification region. In an embodiment, the bias current is a sensed current (for example, shown as sensed current Iₛₑₙ₂ indicative of the load current I_{load}) sensed by the current feedback circuit 203B.

The current feedback circuit 203B may be another specific embodiment of the current feedback circuit 203 in FIG. 2. In an embodiment, the current feedback circuit 203B is configured to sense the load current I_{load} and generate sensed currents (for example, two senses currents Iₛₑₙ₁ and Iₛₑₙ₂ are shown in FIG. 4). In an embodiment, the first sensed current Iₛₑₙ₁ is equal to the second sensed current Iₛₑₙ₂. The first sensed currents Ii flows through the resistor Rlimit, and the other sensed current Iₛₑₙ₂ flows into the bias terminal of the differential amplifier circuit 401. As shown in FIG. 4, the first sensed current Iₛₑₙ₁ is obtained through the transistor 302 and the current sensing circuit 301 connected in series, and the second sensed current Iₛₑₙ₂ is obtained through the transistor 404 and the current sensing circuit 403 connected in series. The sensing process of the second sensed current Iₛₑₙ₂ is the same as the sensing process of the first sensed current Iₛₑₙ₁, which is not repeated here. In another embodiment, the current feedback circuit 203B may also have other structures to obtain a sensed current proportional to the value of the load current I_{load}. For example, the first sensed current Iₛₑₙ₁ can be copied through a current mirror to obtain the second sensed current Iₛₑₙ₂.

FIG. 5 shows an exemplary circuit diagram of the differential amplifier circuit 401, according to an embodiment of the present invention. Referring to FIG. 5, the differential amplifier circuit 401 includes a transistor 501, a transistor 502, a resistor R1 and a resistor R2. The connection relationship of these components is as shown in FIG. 5. In an embodiment, the transistor 501 and the transistor 502 are P-type FET. In an embodiment, the differential amplifier circuit 401 has a symmetrical structure. For example, the transistor 501 and the transistor 502 are a pair of transistors with same characteristics, and the resistor R1 and the resistor R2 are a pair of resistors with same resistance value. In the example shown in FIG. 5, a control terminal of the transistor 501 is configured to receive the sensed voltage Vₛₑₙ indicative of the load current I_{load}, a control terminal of the transistor 502 is configured to receive the reference voltage V_{ref}, a common terminal of the transistor 501 and the resistor R1 is configured to output the first amplified signal INP, a common terminal of the transistor 502 and the resistor R2 is configured to output the second amplified signal INN, and a common terminal of the transistor 501 and the transistor 502 (for example, a common source terminal) receives the second sensed current Iₛₑₙ₂ indicative of the load current I_{load} as a bias current. In this example, when the system is in the steady state, the values of the reference voltage V_{ref} and the sensed voltage Vₛₑₙ are equal, so that a drain current I_{d1} flowing through the transistor 501 and a drain current I_{d2} flowing through the transistor 502 are equal, that is, I_{d1}=I_{d2}=Iₛₑₙ₂/2=K₁×I_{load}/2 (10).

Referring back to FIG. 4, similarly, the circuit structure shown in FIG. 4 forms a current regulation loop for regulating the load current I_{load}, and at the steady state, the gain Loop Gain₂ of the loop can be expressed as the following relationship:

$$Loop {Gain}_{2} = {A}_{401} \times {A}_{305} \times {A}_{304} \times {gm}_{205} \times {R}_{limit} \times {K}_{1} , \qquad ( 11 )$$

where A₄₀₁ represents a gain of the differential amplifier circuit 401, A₃₀₅ represents a gain of the error amplifier circuit 305, A₃₀₄ represents a gain of the transistor 304, gm₂₀₅ represents a transconductance of the switching element 205, Rₗᵢₘᵢₜ represents the resistance value of the resistor Rlimit, and K₁ represents the ratio of the first sensed current Iₛₑₙ₁ to the load current I_{load}.

In the example shown in FIG. 5, since the characteristics of the transistor 501 and the transistor 502 are the same, and the resistance values of the resistor R1 and the resistor R2 are the same, the gain A₄₀₁ of the differential amplifier circuit 401 can be expressed as:

A₄₀₁=gm₁×R₁ (12),
where gm₁ is a transconductance of the transistor 501 (and/or the transistor 502) and R₁ is a resistance value of resistor R1 (and/or the resistor R2).

Combining the relations (4) and (10), the transconductance gm₁ of the transistor 501 (and/or the transistor 502) can be expressed as:

$${gm}_{1} = \sqrt{2 {μ}_{n} {C}_{ox} \frac{W}{L} {K}_{1} {I}_{load} / 2} , \qquad ( 13 )$$

where, μₙ represents the electron mobility of the transistor 501 and/or the transistor 502, Cₒₓ represents a gate oxide capacitance per unit area of the transistor 501 and/or the transistor 502,

$$\frac{W}{L}$$

represents a width-length ratio of the transistor 501 and/or the transistor 502, and I_{load} represents the load current.

Therefore, if the relation (13) is substituted into the relation (12), we can get that A₄₀₁∝\sqrt{I_{load}} (14).

Based on the above, gm₂₀₅ ∝\sqrt{I_{load}}, A₄₀₁∝I_{load},

$${R}_{limit} ∝ \frac{1}{{I}_{load}} ,$$

it can be known that the gain of the current regulating circuit 204B is proportional to a square root of the value of the load current. In addition, a gain of a circuit including the current feedback circuit 203B and the current regulating circuit 204B can be expressed as A₄₀₁×A₃₀₅×A₃₀₄×gm₃₀₂, and since the transistor 302 and the switching element 205 form a mirror circuit structure, it can be known that the gain of the circuit including the current feedback circuit 203B and the current regulating circuit 204B is linearly proportional to the value of the load current I_{load}.

To sum up, the loop gain Loop Gain₂ of the current regulation loop according to an embodiment of the present invention will no longer be related to the load current I_{load}, that is, the loop gain Loop Gain₂ will no longer vary with the set current limit of the load current I_{load}, so that the system can remain stable even when the limit range of load current is wide.

Although some embodiments of the present invention have been described in detail above, it should be understood that these embodiments are only for illustrative purposes and are not used to limit the scope of the present invention. Other feasible alternative embodiments can be known to those of ordinary skill in the art by reading the present disclosure.

What is claimed is:

1. A load switch circuit, comprising:
a switching element, coupled between an input terminal and an output terminal of the load switch circuit; and
a controlling circuit, coupled to the switching element, and configured to regulate a current flowing through the switching element to a set current limit, wherein the controlling circuit is further configured to control a loop formed by the controlling circuit and the switching element based on a sensed signal indicative of the current flowing through the switching element, so that the loop remains stable when a set current limit of the current flowing through the switching element is changed from a first set current limit to a second set current limit.

2. The load switch circuit according to claim 1, wherein the controlling circuit is configured to control a loop gain of the loop based on the sensed signal so that the loop gain remains stable when the set current limit is changed from the first set current limit to the second set current limit.

3. The load switch circuit according to claim 1, further comprising:
a current limit adjusting terminal, coupled to a current limit adjustment element, wherein the set current limit is adjusted from the first set current limit to the second set current limit by adjusting the current limit adjustment element.

4. The load switch circuit according to claim 1, wherein the controlling circuit is further configured to regulate the current flowing through the switching element to increase when it is less than the set current limit and decrease when it is greater than the set current limit based on the sensed signal.

5. The load switch circuit according to claim 1, wherein the controlling circuit comprises:
an operational amplification circuit, configured to receive the sensed signal and a reference signal and is further configured to provide a controlling signal for regulating the current flowing through the switching element.

6. The load switch circuit according to claim 5, wherein the operational amplification circuit has a transconductance proportional to a square root of the current flowing through the switching element.

7. The load switch circuit according to claim 5, wherein the operational amplification circuit comprises:
a first-stage differential operational amplification circuit, configured to receive the sensed signal and the reference signal; and
a second-stage differential operational amplification circuit, coupled in series to the first-stage differential operational amplification circuit, and configured to provide the controlling signal.

8. The load switch circuit according to claim 7, wherein the first-stage differential operational amplification circuit is further configured to receive a bias current, and wherein the bias current comprises a sensed current indicative of the current flowing through the switching element.

9. The load switch circuit according to claim 5, wherein the controlling circuit further comprises:
a second transistor, coupled to the switching element and the operational amplification circuit, and configured to control the switching element based on the controlling signal, so as to adjust the current flowing through the switching element.

10. The load switch circuit according to claim 5, wherein the controlling circuit further comprises:
a current feedback circuit, configured to sense the current flowing through the switching element and obtain a sensed current indicative of the current flowing through the switching element, wherein the sensed signal is generated based on the sensed current.

11. A load switch circuit, comprising:
a switching element, coupled between an input terminal and an output terminal of the load switch circuit; and
a controlling circuit, coupled to the switching element and forming a loop with the switching element, and configured to regulate a current flowing through the switching element to a set current limit, wherein the controlling circuit is configured to control a gain of the controlling circuit to be linearly proportional to the current flowing through the switching element, so that the loop remains stable when the set current limit is changed from a first set current limit to a second set current limit.

12. The load switch circuit according to claim 11, wherein the controlling circuit is configured to control a loop gain of the loop to remain stable when the set current limit is changed from the first set current limit to the second set current limit.

13. The load switch circuit according to claim 11, wherein the controlling circuit comprises:
an operational amplification circuit, configured to provide a controlling signal for regulating the current flowing through the switching element, wherein the operational amplification circuit has a transconductance proportional to a square root of the current flowing through the switching element.

14. The load switch circuit according to claim 13, wherein the operational amplification circuit comprises:
a first-stage differential operational amplification circuit, having a transconductance proportional to the square root of the current flowing through the switching element; and
a second-stage differential operational amplification circuit, coupled in series to the first-stage differential operational amplification circuit, and configured to provide the controlling signal.

15. The load switch circuit according to claim 14, wherein the first-stage differential operational amplification circuit is further configured to receive a bias current, and wherein the bias current comprises a sensed current indicative of the current flowing through the switching element.

16. A controlling circuit of a load switch circuit, wherein the load switch circuit comprises a switching element coupled between an input terminal and an output terminal of the load switch circuit, and wherein,
the controlling circuit is coupled to the switching element, and is configured to regulate a set current limit of a current flowing through the switching element, wherein the controlling circuit is configured to control a loop formed by the controlling circuit and the switching element based on a sensed signal indicative of the current flowing through the switching element, so that the loop remains stable when the set current limit is changed from a first set current limit to a second set current limit.

17. The controlling circuit according to claim 16, configured to control a loop gain of the loop based on the sensed signal so that the loop gain remains stable when the set current limit is changed from the first set current limit to the second set current limit.

18. The controlling circuit according to claim 16, comprising:
an operational amplification circuit, configured to receive the sensed signal and a reference signal and further configured to provide a controlling signal for regulating the current flowing through the switching element.

19. The controlling circuit according to claim 18, wherein the operational amplification circuit has a transconductance proportional to a square root of the current flowing through the switching element.

20. The controlling circuit according to claim 18, wherein the operational amplification circuit comprises:
a first-stage differential operational amplification circuit, configured to receive the sensed signal and the reference signal; and
a second-stage differential operational amplification circuit, coupled in series to the first-stage differential operational amplification circuit, and configured to provide the controlling signal.

21. The controlling circuit according to claim 20, wherein the first-stage differential operational amplification circuit is further configured to receive a bias current, and wherein the bias current comprises a sensed current indicative of the current flowing through the switching element.

22. A controlling circuit of a load switch circuit, wherein the load switch circuit comprises a switching element which is coupled between an input terminal and an output terminal of the load switch circuit, and wherein,
the controlling circuit is coupled to the switching element and forms a loop with the switching element, and is configured to regulate the current flowing through the switching element to a set current limit, and wherein the controlling circuit is configured to control a gain of the controlling circuit to be linearly proportional to the current flowing through the switching element, so that the loop remains stable when the set current limit is changed from a first set current limit to a second set current limit.

23. The controlling circuit according to claim 22, configured to control a loop gain of the loop to remain stable when the set current limit is changed from a first set current limit to a second set current limit.

24. The controlling circuit according to claim 22, comprising:
an operational amplification circuit, configured to provide a controlling signal for regulating the current flowing through the switching element, wherein the operational amplification circuit has a transconductance proportional to a square root of the current flowing through the switching element.

25. The controlling circuit according to claim 24, wherein the operational amplification circuit comprises:
a first-stage differential operational amplification circuit, configured to receive the sensed signal and the reference signal; and
a second-stage differential operational amplification circuit, coupled in series to the first-stage differential operational amplification circuit, and configured to provide the controlling signal.

26. The controlling circuit according to claim 25, wherein the first-stage differential operational amplification circuit is further configured to receive a bias current, and wherein the bias current comprises a sensed current indicative of the current flowing through the switching element.
